(19) United States
(12) Patent Application Publication
(10) Pub. No.: US 2025/0189576 A1
(43) Pub. Date: Jun. 12, 2025

(54) SYSTEMS AND METHODS FOR TESTING SEMICONDUCTOR DEVICE

(71) Applicant: Taiwan Semiconductor Manufacturing Company, Ltd., Hsinchu (TW)

(72) Inventors: Shenggao Li, Hsinchu (TW); Mei-Chen Chuang, Hsinchu (TW)

(73) Assignee: Taiwan Semiconductor Manufacturing Company, Ltd., Hsinchu (TW)

(21) Appl. No.: 18/647,151

(22) Filed: Apr. 26, 2024

Related U.S. Application Data
(60) Provisional application No. 63/609,032, filed on Dec. 12, 2023.

(51) Int. Cl. G01R 31/28

(52) U.S. Cl. CPC G01R 31/2853

(57) ABSTRACT

A circuit includes a signal source configured to provide a test signal to at least one of a plurality of conductive structures based on a decoded signal, a plurality of switches configured to connect the signal source to the plurality of conductive structures, respectively, based on the decoded signal, a multiplexer configured to select a test voltage present on the at least one conductive structure, based on the decoded signal, and an analog-to-digital converter (ADC) configured to provide a digital output based on comparing the test voltage with a reference voltage.

### CROSS-REFERENCE TO RELATED APPLICATION

This application claims priority to and the benefit of U.S. Provisional Application No. 63/609,032, filed Dec. 12, 2023, entitled “DETECTOR CIRCUIT FOR DIE TO DIE INTER-CONNECT,” which is incorporated herein by reference in its entirety for all purposes.

### BACKGROUND

The semiconductor industry has experienced rapid growth due to continuous improvement in the integration density of a variety of electronic components (e.g., transistors, diodes, resistors, capacitors, etc.). For the most part, this improvement in integration density has come from repeated reductions in minimum feature size (e.g., shrinking the semiconductor process node towards the sub-nanometer node), which allows more components to be integrated into a given area. As the demand for miniaturization, higher speed, and greater bandwidth, as well as lower power consumption and latency has grown recently, there has grown a need for advanced packaging techniques for semiconductor dies.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a block diagram of an example circuit for testing a conductive structure, in accordance with various embodiments.

FIG. 2 illustrates a schematic diagram of an example circuit for testing a conductive structure, in accordance with various embodiments.

FIG. 3 illustrates a schematic diagram of a portion of an example circuit for testing a conductive structure, in accordance with various embodiments.

FIG. 4 illustrates a schematic diagram of an example circuit for testing a conductive structure, in accordance with various embodiments

FIG. 5 illustrates a schematic diagram of an example circuit for testing a conductive structure, in accordance with various embodiments.

FIG. 6A and FIG. 6B illustrate embodiments of an example circuit for testing a conductive structure, in accordance with various embodiments.

FIG. 6C and FIG. 6D illustrate example configurations of the first die and the second die shown in FIG. 6A and FIG. 6B, in accordance with various embodiments.

FIG. 7 shows a flow chart of an example method for operating a circuit for testing a conductive structure, in accordance with various embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A modern semiconductor device may be formed as an integrated circuit (e.g., semiconductor dies, semiconductor chips, integrated circuit (IC) chips, etc.), operatively and physically coupled to one another. In a semiconductor device, different IC dies/chips (e.g., with logic functionality) can be coupled to each other through one or more interconnect structures (e.g., without logic functionality) such as die-to-die structures, while having one or more semiconductor structures therein (e.g., through-silicon-vias (TSVs), super power rails (SPRs), etc.). Over time, one or more interconnect structures and/or one or more semiconductor structures within the device may degrade, resulting in an undesired change (e.g., increase) in resistance through the structures. In modern devices including hundreds, or even thousands, of such structures, it is difficult to detect and locate the degraded structures. For example, RC characteristics of an individual structure can be so small that it is difficult to detect an outlier. By placing all of the structures in a device in series and plotting the measured resistance, a statistical model may be used to detect degraded structures generally. But such a test may not be precise enough to pick up such small variations in resistance while requiring significant manual efforts. Alternatively, degraded structures can be detected by measuring a delay caused by each structure in a device; however at the small scales of modern devices, even if resistance through a degraded structure becomes 10,000 times larger, the delay difference may only be around 10 picoseconds, which may be difficult to detect. Thus, there is a need for techniques for testing/monitoring quality of an integrated circuit (e.g., the interconnect structures and/or the semiconductor structures discussed above).

To overcome these issues, embodiments described herein may provide techniques for testing/monitoring interconnect structures (e.g., die-to-die structures for testing/monitoring die to die connectivity quality, inter-die structure resistance distribution, etc.) and/or semiconductor structures (e.g., TSVs, SPRs, etc.) with improved resistance resolution. Furthermore, embodiments described herein may provide in-situ testing/monitoring techniques, allowing for yield analysis and/or yield improvement (e.g., of the interconnect structures and/or the semiconductor structures), while detecting a defect.

As described herein, a circuit can test a conductive structure, which may be or include an interconnect structure and/or a semiconductor structure within an IC as discussed above. The circuit can include a signal source to provide a test signal to at least one of a plurality of conductive structures based on a decoded signal. In some embodiments, the signal source can provide a test signal, through a plurality of switches, to a plurality of conductive structures. For example, the plurality of switches can connect the signal source to the plurality of conductive structures, respectively, based on the decoded signal. The circuit can include a multiplexer to select a test voltage present on at least one conductive structure of a plurality of conductive structures, based on a decoded signal. In some embodiments, the multiplexer can receive a test voltage of at least one of the plurality of conductive structures to test the conductive structure. The circuit can include an analog-to-digital converter (ADC) to provide a digital output based on comparing a test voltage with a reference voltage. In some embodiments, the ADC can receive a test voltage or a signal associated therewith, and output an output signal that represents a resistance of the one selected conductive structure. In some embodiments, the ADC may be or include one-bit-sigma delta ADC for a higher resolution, thereby reducing a current needed and routing areas.

This allows for the circuit to measure a voltage difference by the ADC (e.g., rather than sensing a delay difference as discussed above). Thus, the circuit can test/monitor the interconnect structures and/or the semiconductor structures with improved resistance resolution, and allow for yield analysis and/or yield improvement of ICs, for example, through an in-situ operation (e.g., detect testing/monitoring while operating the IC or the conductive structure). In addition, this can further help for yield learning/improvement and maintenance (e.g., lane repair, etc.).

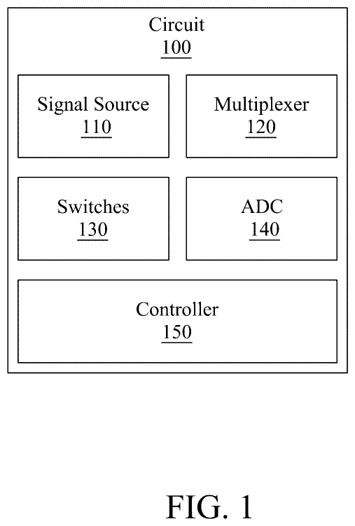

FIG. 1 illustrates a block diagram of an example circuit 100 for testing a conductive structure, in accordance with various embodiments. The circuit 100 can include a signal source 110, a multiplexer 120, switch 130, an analog-to-digital converter (ADC) 140, and a controller 150.

The circuit 100 can be used to test/monitor a conductive structure of an integrated circuit (IC). In some embodiments, the conductive structure may be or include a connector structure within multiple bonded dies. In some embodiments, the conductive structure may be or include a connector structure between two bonded dies. For example, the circuit 100 can test or monitor any number and/or combination of interconnect structures and/or semiconductor structures in one or more ICs. In some embodiments, such an IC can include a substrate and conductive structures (e.g., a semiconductor structure, an interconnect structure, etc. as discussed above). For example, the IC and/or a die therein can include a via configured to carry signals between components below the substrate and components above the substrate, such as a TSV or a SPR as described above. The IC and/or a die therein can include interconnect and/or metallization structure configured to connect the via to components on or in the substrate or to establish a connection between dies. In some embodiments, the conductive structure may be or include at least one of through-silicon-vias (TSVs), super power rails (SPRs), a uBump, a hybrid bond, or any interconnect structure between dies. The circuit 100 can test/monitor a test voltage associated with the semiconductor structure (e.g., the via) and the interconnect structure (e.g., the die to die structures). In some embodiments, the circuit 100 can test/monitor connectivity between dies of a three-dimensional integrated circuit (3DIC). In some embodiments, the circuit 100 can detect a yield of such a 3DIC. In some embodiments, the circuit 100 can be used to test/monitor a device under testing (DUT) (e.g., ICs, dies, conductive structures, etc.) during an operation of the DUT. For example, the circuit 100 may be or include an in-situ circuit configured to test/monitor a conductive structure within the DUT during an operation of the conductive structure and/or the DUT.

In some embodiments, the circuit 100 can include the signal source 110. The signal source 110 can provide a test signal to at least one of a plurality of conductive structures based on a decoded signal. In some embodiments, the signal source 110 can provide a test signal, through at least one of the switches 130, to a plurality of conductive structures. For example, the switches 130 can connect the signal source 110 to the plurality of conductive structures, respectively, based on the decoded signal. In some embodiments, the circuit 100 can include the multiplexer 120. In some embodiments, the multiplexer 120 can select a test voltage present on at least one conductive structure of a plurality of conductive structures, based on a decoded signal. In some embodiments, the multiplexer 120 can receive a test voltage of at least one of the plurality of conductive structures to test the conductive structure. In some embodiments, the circuit 100 can include the ADC 140. In some embodiments, the ADC 140 can provide a digital output based on comparing the test voltage with a reference voltage. In some embodiments, the ADC 140 can receive the test voltage or a signal associated therewith, and output an output signal that represents a resistance of the one selected conductive structure (e.g., the conductive structure corresponding to the selected test voltage). In some embodiments, the ADC 140 may be or include one-bit-sigma delta ADC for a higher resolution, thereby reducing a current needed and routing areas.

The signal source 110 can be configured to provide a test signal to at least one of the conductive structures. In some embodiments, the signal source 110 may be or include a circuit, circuitry, or any component that generates a current. In some embodiments, the signal source 110 may be or include a current source configured to provide a current supply (e.g., as a test signal). The signal source 110 can be electrically coupled to at least one of the conductive structures through at least one of the switches 130. In some embodiments, the signal source 110 can provide a test signal to at least one of the conductive structures through at least one of the switches 130.

The switches 130 can be configured to connect the signal source 110 to at least one of the conductive structures. In some embodiments, the switches 130 can be configured to connect the signal source 110 to the plurality of conductive structures, respectively, based on a decoded signal. In some embodiments, the switches 130 may be or include any semiconductor device (e.g., a BJT, a MOSFET, etc.), any semiconductor diode, any semiconductor switch, or any component that can control a current flow of the switch path (e.g., connecting the signal source 110 and the conductive structures).

The multiplexer 120 can be configured to connect with at least one of the conductive structures. In some embodiments, the multiplexer 120 can be configured to select a test voltage present on one of the conductive structures, based on a decoded signal. For example, the multiplexer 120 can receive a test voltage of a selected one of the conductive structures at a time. In some embodiments, the multiplexer 120 may be or include an analog multiplexer configured to route analog signals.

The ADC 140 can be configured to provide a digital output. In some embodiments, the ADC 140 can provide the digital output based on comparing the test voltage with a reference voltage. In some embodiments, the digital output can be an output signal that represents a resistance of the selected one of the conductive structures (e.g., the conductive structure corresponding to the selected one test voltage). In some embodiments, the ADC 140 may be or include a system, a device, or any circuit component to convert an analog signal into a digital signal. In some embodiments, the ADC 140 may be or include a system, a device, or any circuit component to output a signal that represents a resistance of a selected one of the plurality of conductive structures based on the test voltage. In some embodiments, the ADC 140 may be or include a sigma delta ADC. In some embodiments, the ADC 140 may be or include a one-bit-sigma delta ADC. In some embodiments, the ADC 140 can be configured to output the digital output during an operation of the conductive structures (e.g., during an operation of bonded dies). In some embodiments, the ADC 140 can be configured to output a sequence of digital outputs corresponding to the plurality of conductive structures. For example, each signal or bit of the sequence can correspond to each of the plurality of conductive structures. In some embodiments, the ADC 140 can be configured to connect with the conductive structures through the multiplexer 120. The ADC 140 can receive a signal (e.g., the test voltage) from the multiplexer 120 and can output a digital signal that represents a resistance of the selected one of the conductive structures based on the test voltage.

The controller 150 can be configured to control at least one of the signal source 110, the multiplexer 120, the switches 130, and the ADC 140. The controller 150 may be or include a circuit, circuitry, or any component that can control at least one of the signal source 110, the multiplexer 120, the switches 130, and the ADC 140.

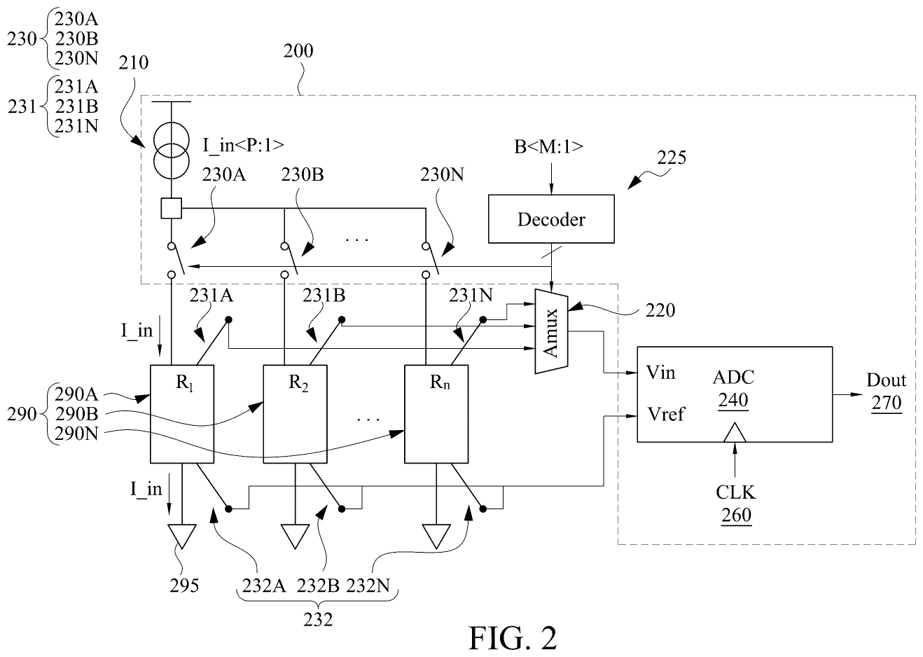

FIG. 2 illustrates a schematic diagram of an example circuit 200 for testing a conductive structure, in accordance with various embodiments. The circuit 200 includes a signal source 210, a multiplexer 220, switches 230 (e.g., a switch 230A to connect with the first conductive structure 290A, a switch 230B to connect with the second conductive structure 290B, and a switch 230N to connect with the n-th conductive structure 290N), and an ADC 240. The circuit 200 may be substantially similar to or incorporate features of the circuit 100. In some embodiments, the signal source 210, the multiplexer 220, the switches 230, and the ADC 240 may be substantially similar to or incorporate features of the signal source 110, the multiplexer 120, the switches 130, and the ADC 140, respectively. In some embodiments, the circuit 200 can include a decoder 225 configured to provide a decoded signal.

In some embodiments, the circuit 200 can test at least one of conductive structures 290 (e.g., a first conductive structure 290A, a second conductive structure 290B, and an N-th conductive structure 290N). In some embodiments, the conductive structures 290 may be or include at least one of through-silicon-vias (TSVs), super power rails (SPRs), a uBump, a hybrid bond, or an interconnect structure between dies. In some embodiments, the conductive structures 290 may be or include a connector structure within multiple bonded dies. In some embodiments, the conductive structures 290 may be or include a connector between two bonded dies. The circuit 200 may be a non-limiting example of the circuit 100.

The circuit 200 can be used to test/monitor at least one of the conductive structures 290. In some embodiments, the conductive structures 290 may be of an integrated circuit (IC). In some embodiments, the conductive structures 290 may be or include a connector structure within multiple bonded dies. In some embodiments, the conductive structures 290 may be or include a connector structure between two bonded dies. For example, the circuit 200 can test or monitor any number and/or combination of interconnect structures and/or semiconductor structures in one or more ICs. In some embodiments, such an IC can include a substrate and conductive structures (e.g., a semiconductor structure, an interconnect structure, etc. as discussed above). For example, the IC and/or a die therein can include a via configured to carry signals between components below the substrate and components above the substrate, such as a TSV or a SPR as described above. The IC and/or a die therein can include interconnect and/or metallization structure configured to connect the via to components on or in the substrate or to establish a connection between dies. In some embodiments, the conductive structures 290 may be or include at least one of through-silicon-vias (TSVs), super power rails (SPRs), a uBump, a hybrid bond, or any interconnect structure between dies. The circuit 200 can test/monitor a test voltage associated with the semiconductor structure (e.g., the via) and the interconnect structure (e.g., the die to die structures). In some embodiments, the circuit 200 can test/monitor connectivity between dies of a three-dimensional integrated circuit (3DIC). In some embodiments, the circuit 200 can detect a yield of such a 3DIC. In some embodiments, the circuit 200 can be used to test/monitor a device under testing (DUT) (e.g., ICs, dies, conductive structures, etc.) during an operation of the DUT. For example, the circuit 200 may be or include an in-situ circuit configured to test/monitor at least one of the conductive structures 290 within the DUT during an operation of the conductive structures 290 and/or the DUT.

In some embodiments, the circuit 200 can include the signal source 210. The signal source 210 can provide a test signal to at least one of the conductive structures 290 based on a decoded signal from the decoder 225. In some embodiments, the signal source 210 can provide a test signal, through at least one of the switches 230, to a corresponding one of the conductive structures 290. For example, the switches 230 can connect the signal source 210 to the conductive structures 290, respectively, based on a decoded signal from the decoder 225. In some embodiments, the circuit 200 can include the multiplexer 220. In some embodiments, the multiplexer 220 can receive a test voltage of at least one of the conductive structures 290 to test the conductive structure. In some embodiments, the circuit 200 can include the ADC 240. In some embodiments, the ADC 240 can provide a digital output based on comparing the test voltage with a reference voltage. In some embodiments, the ADC 240 can receive the test voltage or a signal associated therewith, and output an output signal that represents a resistance of the one selected conductive structure (e.g., the conductive structure corresponding to the selected test voltage). In some embodiments, the ADC 240 may be or include one-bit-sigma delta ADC for a higher resolution, thereby reducing a current needed and routing areas. For example, the ADC 240 may be or include one-bit-sigma delta ADC configured to operate with a single quantization level (e.g., create a stream of 1-bit digital data).

In some embodiments, the circuit 200 can include first conductive lines 231 (e.g., a first conductive line 231A connected to the first conductive structure 290A, a first conductive line 231B connected to the second conductive structure 290B, a first conductive line 231N connected to the n-th conductive structure 290N, etc.). In some embodiments, the circuit 200 can include second conductive lines 232 (e.g., a second conductive line 232A connected to the first conductive structure 290A, a second conductive line 232B connected to the second conductive structure 290B, a second conductive line 232N connected to the n-th conductive structure 290N, etc.).

In some embodiments, the signal source 210 can be configured to provide a test signal I_in<P:1> to the conductive structures 290. For example, when the switch 230A is closed, the signal source 210 can provide a test signal I_in to the first conductive structure 290A through the switch 230A. As shown, a current can pass through the first conductive structure 290A from a first end (e.g., an upper portion) to a second end (e.g., a lower portion), which is connected to ground 295. Likewise, the switch 230B can be configured to connect the signal source 210 to the first end of the conductive structure 290B, to the second end of the conductive structure 290B, and to ground. In a similar fashion, the current source 210 can be selectively provided to the conductive structures 290 via the switches 230 to sink through the selected one of the conductive structures 290 to ground.

In some embodiments, the multiplexer 220 can be connected to at least one of the conductive structures 290 through the respective first conductive lines 231 to receive test voltages of the conductive structures 290. For example, the multiplexer 220 can be connected to the first conductive structure 290A through the first conductive line 231A to receive a test voltage of the first conductive structure 290A, the multiplexer 220 can be connected to the second conductive structure 290B through the first conductive line 231B to receive a test voltage of the second conductive structure 290B, and the multiplexer 220 can be connected to the n-th conductive structure 290N through the first conductive line 231N to receive a test voltage of the n-th conductive structure 290N. In some embodiments, the multiplexer 220 can be configured to select a test voltage present on at least one of the conductive structures 290, based on a decoded signal. For example, the multiplexer 220 can select a test voltage present on the first conductive structure 290A, based on a decoded signal from the decoder, the decoded signal indicating the first conductive structure 290A. In some embodiments, the first conductive lines 231 may be or include a second switch. In some embodiments, the second conductive lines 232 may be or include a third switch. The multiplexer 220 can provide a test voltage received from at least one of the conductive structures 290 to the ADC 240. In some embodiments, the multiplexer 220 can be connected to an input Vin of the ADC 240 to provide test voltages of the conductive structures 290 to the ADC 240.

In some embodiments, the ADC 240 can be connected to the conductive structures 290 through the multiplexer 220 to receive the test voltages of the conductive structures 290. In some embodiments, the ADC 240 can be connected to the conductive structures 290 through the second conductive lines 232. As shown, the second conductive lines 232 can be connected to the second end of the conductive structures 290, while the first conductive lines 231 can be connected to the first end of the conductive structures 290. In some embodiments, the first conductive lines 231 can be connected to the ADC 240 at a first input Vin of the ADC 240. In some examples, the second conductive lines 232 can be all shorted together and/or can be connected to a reference point Vref of the ADC 240, providing a reference point to the test voltages received from the multiplexer 220. In some embodiments, the ADC 240 can be configured to provide a digital output Dout 270 that represents a resistance of at least one of the conductive structures 290 based on the test voltage received from the multiplexer 220.

In some embodiments, as shown in FIG. 2, when the first switch 230A is closed, a closed circuit, including the first conductive structure 290A, is formed such that the current I_in passes through the conductive structure 290A. The first conductive lines 231 and the second conductive lines 232 can create a sensing path connected to the input Vin through the multiplexer 220 and to the reference point Vref, which can measure a voltage difference across the first conductive structure 290A. The ADC 240 can convert an analog signal corresponding to the voltage difference into a digital signal, the digital output Dout 270.

In some embodiments, the digital output Dout 270 may be a binary signal that outputs a “1” (high) or “0” (low) based on the measured voltage difference. The ADC 240 may be configured to switch from low to high, or high to low, at a particular input threshold voltage. This threshold voltage may be set such that it corresponds to a resistance through one of the conductive structures 290 that indicates a degraded structure. Accordingly, the circuit 200 can measure whether one of the conductive structures 290 is degraded based on whether the ADC 240 outputs a high signal or a low signal. In some embodiments, a controller (e.g., the controller 150) can toggle the switches 230 on and off in a specific order, thereby connecting the different conductive structures 290 to the ADC 240 one at a time. In some embodiments, the ADC 240 can be configured to output a sequence of digital outputs (e.g., Dout 270) corresponding to the conductive structures 290. For example, the digital output Dout 270 of the ADC 240 can represent a voltage measurement for each of the conductive structures 290 in the sequence. By monitoring the digital output Dout 270 of the ADC 240, the presence and/or location of a degraded structure can be determined.

In some embodiments, the circuit 200 may include a controller (e.g., the controller 150 in FIG. 1). The controller can control the decoder 225 configured to receive a plurality of bits to control the switches 230. For example, the controller can provide a signal B<M:1> to the decoder 225, the signal including a bit to turn on one of the switches 230, thereby controlling the switches 230. The decoder 225 can provide a decoded signal (e.g., an n-bit signal) to select and turn on one of the switches 230. For example, the decoder 225 can provide a decoded signal one-hot<00010 . . . 0> to select one of the switches 230 corresponding to the bit “1” and turn on the same, thereby allowing for a current to be supplied from the signal source 210 to the corresponding conductive structure 290.

In some embodiments, the ADC 240 can be connected to a clock generator to receive a clock signal CLK 260. In some embodiments, the ADC 240 can be configured to output the digital output Dout 270 based on the clock signal CLK 260. The clock signal CLK 260 can be in synchronization with the decoder 225, such that the ADC 240 can provide the digital output Dout 270 corresponding to one of the switches 230 and the conductive structures 290 corresponding to the bit “1” in the decode signal. For example, the decoder 225 can provide the decode signal to select one of the switches 230 and the conductive structures 290, and the multiplexer 220 can receive a test voltage of the selected one of the conductive structures 290 and provide the test voltage to the ADC 240. The ADC 240, in synchronization with the clock signal CLK 260, can output the digital output Dout 270 that represents a resistance of the selected one of the conductive structures 290 based on the test voltage.

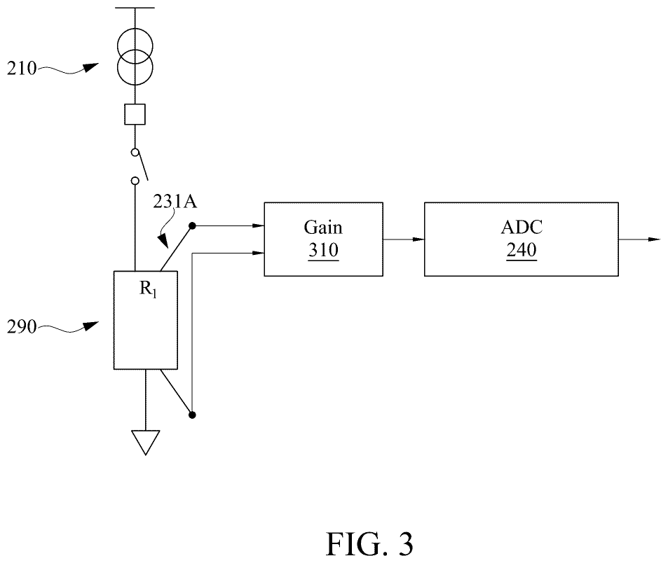

FIG. 3 illustrates a schematic diagram of a portion of an example circuit 300 for testing a conductive structure, in accordance with various embodiments. The circuit 300 includes the signal source 210 and the ADC 240 discussed with respect to FIG. 2, and can additionally include a gain component 310. In some embodiments, the gain component 310 may be or include an amplifier. In some embodiments, the gain component 310 can be configured to connect at least one of the conductive structures 290 to the ADC 240. In some embodiments, the gain component 310 can receive a test voltage from the conductive structure 290 and provide an amplified test voltage to the ADC 240.

In some embodiments, the ADC 240 may be a 10-bit ADC with a resolution of the least significant bit (V_{LSB}), about 1 mV. The minimal detectable resistance, R_{LSB}, can be determined to be V_{LSB}/I_in. For example, when a nominal resistance of a uBump, Rnom, is 0.01 Ohm, 100 mA is needed to have 1 mV voltage difference. However, it is challenging to pass 100 mA through switch devices. When Rnom of a TSV is 0.1 Ohm, only 10 mA is needed to cause a voltage difference of 1 mV. Since increasing the ADC resolution can be expensive, introducing the gain component 310 can improve the detection resolution, with a smaller input current. For example, with the gain component 310, the minimal detectable resistance, R_{LSB}, can be determined to be V_{LSB}/I_in/Gain. In some embodiments, a gain range of the gain component 310 may be from 5 to 20.

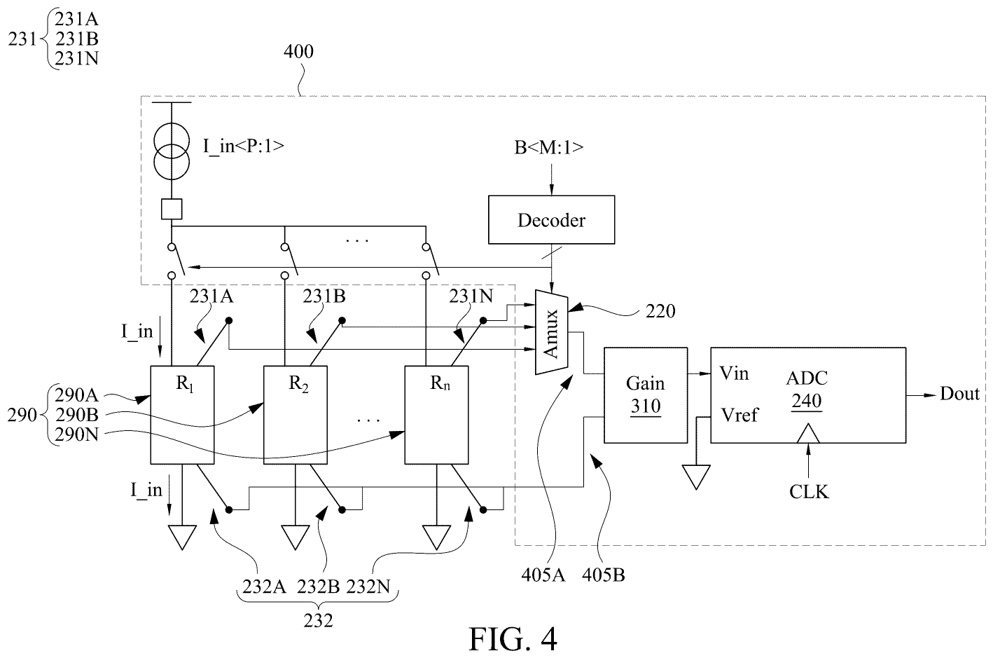

FIG. 4 illustrates a schematic diagram of an example circuit 400 for testing a conductive structure, in accordance with various embodiments. The circuit 400 may be substantially similar to or incorporate features of the circuit 100 and/or the circuit 200. In some embodiments, as shown in FIG. 4, the circuit 400 may be the circuit 200, additionally including the gain component 310 discussed in FIG. 3. The circuit 400 is a non-limiting example of the circuit 200 including the gain component 310.

As shown in FIG. 4, the gain component 310 can connect the conductive structures 290 and the ADC 240. In some embodiments, as shown, the gain component 310 can be configured to receive a test voltage for at least one of the conductive structures 290 by sensing a test voltage between a first end 405A and a second end 405B. At the first end 405A, the gain component 310 is connected to, through the multiplexer 220, the first end of the conductive structures 290. At the second end 405B, the gain component 310 is connected to the second end of the conductive structures 290. The gain component 310 can thereby sense a test voltage for a corresponding one of the conductive structures 290, and provide the test voltage to the ADC 240 through the input Vin. In some embodiments, the second end of the conductive structures 290 can be coupled to ground. As discussed above, the gain component 310 can improve a detection resolution of the circuit 400, with a smaller input current.

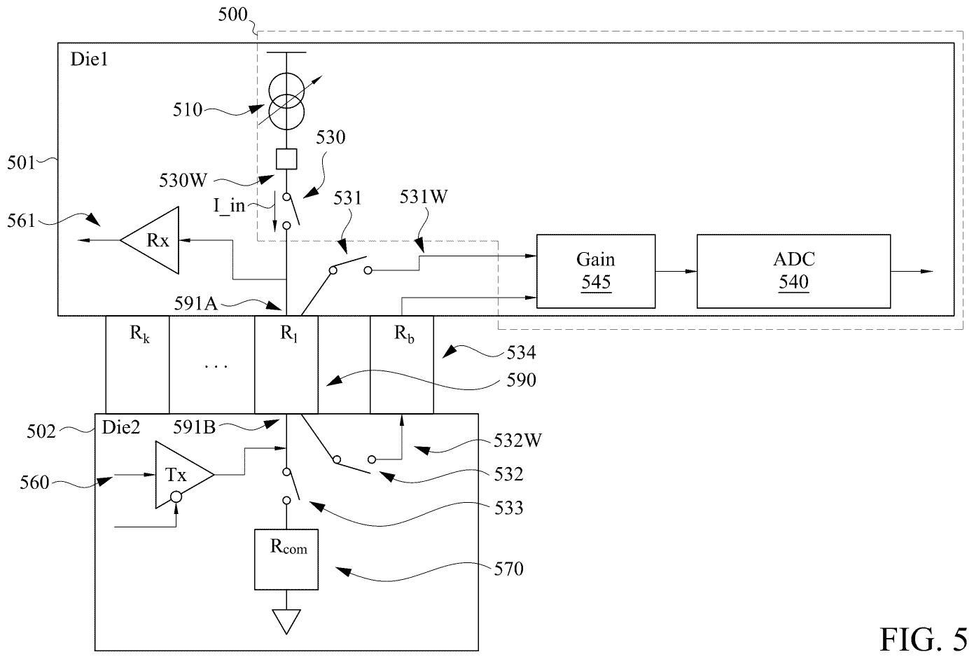

FIG. 5 illustrates a schematic diagram of an example circuit 500 for testing a conductive structure, in accordance with various embodiments. The circuit 500 may be substantially similar to or incorporate features of the circuit 100, the circuit 200, and/or the circuit 400. As shown in FIG. 5, the circuit 500 may include a signal source 510, a switch 530, an ADC 540, and a gain component 545, which may be substantially similar to or incorporate features of the signal source 110, the switch 130, the ADC 140, and the gain component 310, respectively. The circuit 500, switches 531, 532, and 533 can operate to test a conductive structure 590.

In some embodiments, the circuit 500 can be connected with or incorporated within at least one of a first die Diel and a second die 502. For example, as shown in FIG. 5, the circuit 500 can be incorporated within the first die 501. In some embodiments, the second die 502 can be connected with the first die 501 through at least one conductive structure 590. For example, the first die 501 and the second die 502 can be connected through the conductive structure 590 between the first die 501 and the second die 502. In some embodiments, the conductive structure 590 can be within at least one of the first die 501 or the second die 502.

In some embodiments, at least one of the first die 501 and the second die 502 can include the signal source 510. For example, as shown in FIG. 5, the signal source 510 can be incorporated within the first die 501. In some embodiments, the signal source 510 can be connected to the switch 530 configured to connect the signal source 510 to the conductive structure 590. In some embodiments, the signal source 510 can be connected to the switch 530 configured to connect the signal source 510 to the conductive structure 590 through a first wire 530W.

In some embodiments, at least one of the first die 501 and the second die 502 can include the ADC 540. For example, as shown in FIG. 5, the ADC 540 can be incorporated within the first die 501. In some embodiments, the ADC 540 can be connected to the conductive structure 590 through a second wire 531W at a first end 591A of the conductive structure 590. In some embodiments, the ADC 540 can be connected to the conductive structure 590 through a third wire 532W at a second end 591B of the conductive structure 590. In some embodiments, at least one of the first die 501 and the second die 502 can include a resistor 534 or be connected through the resistor 534. In some embodiments, the resistor 534 can be configured to connect the ADC 540 to the second end 591B of the conductive structure 590. In some embodiments, the resistor 534 can form a signal path from the second die 502 to the first die 501, thereby forming a reference voltage point. The resistor 543 can have any value.

In some embodiments, the circuit 500 can be an in-situ testing circuit, such that the ADC 540 can be configured to output a digital output (e.g., Dout 270) during an operation of the conductive structure 590 (and/or of the first die 501 and the second die 502). In some embodiments, at least one of the first die 501 and the second die 502 can include a first terminal 560 to provide an input signal to the conductive structure 590. In some embodiments, at least one of the first die 501 and the second die 502 can include a second terminal 561 to receive an output of the conductive structure 590. In some embodiments, the circuit 500 can be configured to sense a test voltage of the conductive structure 590, while operating the conductive structure 590, for example, by receiving an input through the first terminal 560 (e.g., Tx) and providing an output through the second terminal 561 (e.g., Rx). To test a quality of the conductive structure 590 (e.g., to sense the test voltage, and thus to measure a resistance of the conductive structure 590), the switches 530, 531, 532, 533 can be turned on, with the Tx 560 being at high-Z state. In some embodiments, the ADC 540 may be or include one-bit sigma delta ADC. For example, the ADC 540 may be or include one-bit-sigma delta ADC configured to operate with a single quantization level (e.g., create a stream of 1-bit digital data). In some embodiments, a resistor Rcom 570 can be added to shift a common mode voltage on the conductive structure 590. For example, when a gain stage is a differential amplifier, and/or an input is to be at a middle voltage rail (e.g., Vdd/2, or a voltage between Vss and Vdd), the resistor Rcom 570 can be added to shift the common mode voltage. The common mode voltage may be, R_com×I_in=V, and V may be a voltage close to the common mode voltage for the gain stage (or a voltage reference to connect the second end of the conducting structure 290 to a voltage source).

In some embodiments, the gain component 545 can amplify a test voltage (e.g., a voltage difference measured through the second wire 531W and the third wire 532W) and provide an amplified signal to the ADC 540. The ADC 540 can receive the test voltage from the gain component 545 and output a signal that represents a resistance of the conductive structure 590 based on the test voltage.

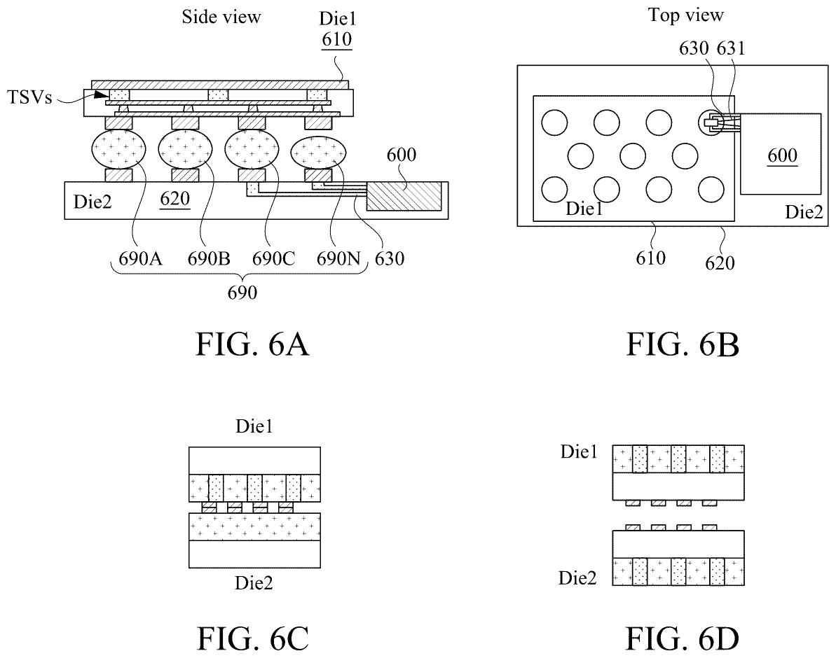

FIG. 6A and FIG. 6B illustrate embodiments of an example circuit 600 for testing a conductive structure, in accordance with various embodiments. FIG. 6A shows a side view of the circuit 600 for conductive structures 690 interconnecting a first die 610 and a second die 620, and FIG. 6B shows a top view of the circuit 600. The circuit 600 may be substantially similar to or incorporate features of the circuit 100, the circuit 200, and/or the circuit 400. Although the circuit 600 is shown to test the conductive structures 690 that are to interconnect the first die 610 and the second die 620, the circuit 600 can be used to test a semiconductor structure within the first die 610 and/or the second die 620. For example, the first die 610 can include a TSV, which can be tested using the circuit 600.

As shown, the circuit 600 can be connected to the conductive structures 690 through conductive lines 630 and 631. The conductive lines 630 may include switches (e.g., the switches 230), which can allow the respective conductive structure to receive a test signal from a signal source (e.g., the signal source 210). The conductive lines 631 shown in FIG. 6B may be connected to an ADC (e.g., the ADC 240), thereby sensing a test voltage of the conductive structure 690 and providing the same to the ADC.

For example, as shown in FIG. 6A, an interconnect structure (e.g., the conductive structure 690N) between the first die 610 and the second die 620 may be open. Such a connectivity quality between the first die 610 and the second die 620 can be detected, monitored, and/or tested using the circuit 600. As discussed above, a signal source can provide a test signal to the conductive structures 290. When the switch connected to the conductive structure 690N is closed (e.g., turned on), the signal source can be connected to the conductive structure 690N. The circuit 600 can then sense a test voltage between the first die 610 and the second die 620 across the conductive structure 690N, using the conductive lines 631. In some embodiments, a multiplexer (e.g., the multiplexer 120) can be used to select one of the conductive structures 690 one at a time. The circuit 600 output a signal that represents a resistance of the one selected conductive structure (e.g., the conductive structure 690N). In some embodiments, as shown in FIG. 6A, when the conductive structure 690N is “open,” the output signal from the circuit 600 may indicate a quality of connectivity (e.g., “open”) of the conductive structure 690N.

In some embodiments, the first die 610 and/or the second die 620 may be or include a silicon-on-chip (SoC) die, an interposer die, etc. In some embodiments, the first die 610 and/or the second die 620 can be interconnected through various interconnect structures (e.g., uBump, TSVs, hybrid bonds, etc.). In some embodiments, the first die 610 and/or the second die 620 may include metal routing layers, which can include the conductive lines 630, 631.

FIG. 6C and FIG. 6D illustrate example configurations of the first die 610 and the second die 620 shown in FIG. 6A and FIG. 6B, in accordance with various embodiments. The circuit 600 can be used to test/monitor an interconnect quality of any inter-die configurations in a 3DIC setting. In some embodiments, as shown in FIG. 6C, the first die 610 and the second die 620 can be arranged face-to-back, such that a front surface of the first die 610 faces a back surface of the second die 620. In some embodiments, as shown in FIG. 6C, the first die 610 and the second die 620 can be arranged face-to-face, such that a front surface of the first die 610 faces a front surface of the second die 620. Shown in FIG. 6C and FIG. 6D are merely non-limiting examples, and any configuration (e.g., 3DIC) of interconnection between dies can be tested/monitored using the circuit disclosed herein.

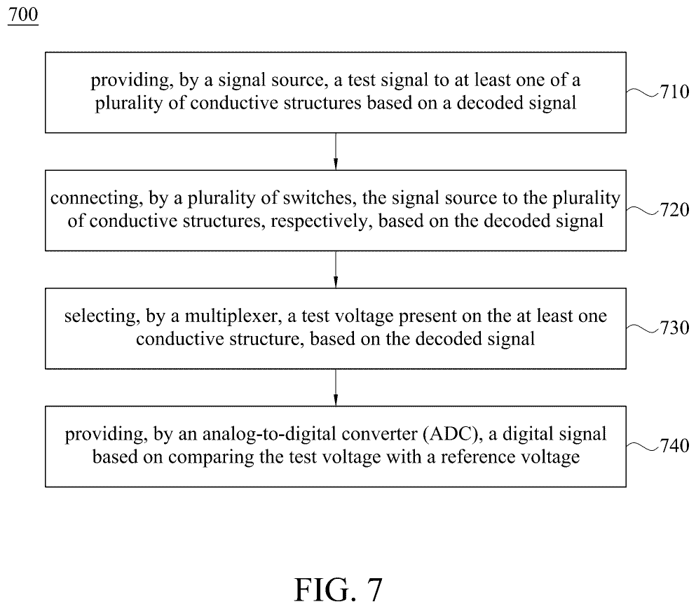

FIG. 7 shows a flow chart of an example method 700 for operating a circuit (e.g., the circuits 100, 200, 400, 500) for testing a conductive structure, in accordance with various embodiments. The method 700 may be performed by, with, or using a circuit (e.g., the circuits 100, 200, 400, 500). It is noted that the method 700 is merely an example and is not intended to limit the present disclosure. Accordingly, it is understood that additional operations may be provided before, during, and after the method 700 of FIG. 7, and that some other operations may only be briefly described herein.

In a brief overview, the method 700 can start with operation 710 of providing, by a signal source (e.g., the signal source 210), a test signal to at least one of a plurality of conductive structures (e.g., the conductive structures 290) based on a decoded signal. The method 700 can continue to operation 720 of connecting, by a plurality of switches (e.g., the switches 230), the signal source to the plurality of conductive structures, respectively, based on the decoded signal. The method 700 can continue to operation 730 of selecting, by a multiplexer (e.g., the multiplexer 220), a test voltage present on the at least one conductive structure, based on the decoded signal. The method 700 can continue to operation 740 of providing, by an analog-to-digital converter (ADC) (e.g., the ADC 240), a digital signal (e.g., Dout 270) based on comparing the test voltage with a reference voltage.

At operation 710, a signal source (e.g., the signal source 210) can provide a test signal to at least one of a plurality of conductive structures (e.g., the conductive structures 290) based on a decoded signal. In some embodiments, the signal source can provide a test signal, through at least one of switches (e.g., the switches 230), to a corresponding one of the plurality of conductive structures (e.g., the conductive structures 290).

At operation 720, a plurality of switches (e.g., the switches 230) can connect the signal source to the plurality of conductive structures, respectively, based on the decoded signal. In some embodiments, the switches can connect the signal source to the conductive structures, respectively, based on a decoded signal from a decoder (e.g., the decoder 225).

At operation 730, a multiplexer (e.g., the multiplexer 220) can select a test voltage present on the conductive structure, based on the decoded signal. In some embodiments, the multiplexer can receive a test voltage of at least one of the conductive structures to test the conductive structure.

At operation 740, an analog-to-digital converter (ADC) (e.g., the ADC 240) can provide a digital signal based on comparing the test voltage with a reference voltage. In some embodiments, the ADC can provide a digital output (e.g., Dout 270) based on comparing the test voltage with a reference voltage. In some embodiments, the ADC can receive the test voltage or a signal associated therewith, and output an output signal that represents a resistance of the conductive structure (e.g., the conductive structure corresponding to the selected test voltage). In some embodiments, the ADC may be or include one-bit-sigma delta ADC for a higher resolution, thereby reducing a current needed and routing areas.

In some embodiments, the method 700 can include amplifying, by a gain component (e.g., the gain component 310), the test voltage. In some embodiments, the gain component may be or include an amplifier configured to receive a test voltage and amplify the same. In some embodiments, the method 700 can include outputting the digital output during an operation of the conductive structure.

In one aspect of the present disclosure, a circuit is disclosed. The circuit includes a signal source configured to provide a test signal to at least one of a plurality of conductive structures based on a decoded signal, a plurality of switches configured to connect the signal source to the plurality of conductive structures, respectively, based on the decoded signal, a multiplexer configured to select a test voltage present on the at least one conductive structure, based on the decoded signal, an analog-to-digital converter (ADC) configured to provide a digital output based on including the test voltage with a reference voltage.

In another aspect of the present disclosure, a circuit for testing a conductive structure is disclosed. The circuit includes a first die, a second die, at least one conductive structure between the first die and the second die or within at least one of the first die or the second die, a signal source within one of the first die or the second die, at least one switch configured to connect the signal source to the at least one conductive structure through a first wire, an analog-to-digital converter (ADC) within one of the first die or the second die, the ADC connected to the at least one conductive structure through a second wire at a first end of the at least one conductive structure and through a third wire at a second end of the at least one conductive structure.

In yet another aspect of the present disclosure, a method for simulating a semiconductor package is disclosed. The method includes providing, by a signal source, a test signal to at least one of a plurality of conductive structures based on a decoded signal, connecting, by a plurality of switches, the signal source to the plurality of conductive structures, respectively, based on the decoded signal, selecting, by a multiplexer, a test voltage present on the at least one conductive structure, based on the decoded signal, providing, by an analog-to-digital converter (ADC), a digital signal based on including the test voltage with a reference voltage.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A circuit, comprising:
a signal source configured to provide a test signal to at least one of a plurality of conductive structures based on a decoded signal;
a plurality of switches configured to connect the signal source to the plurality of conductive structures, respectively, based on the decoded signal;
a multiplexer configured to select a test voltage present on the at least one conductive structure, based on the decoded signal; and
an analog-to-digital converter (ADC) configured to provide a digital output based on comparing the test voltage with a reference voltage.

2. The circuit of claim 1, wherein the at least one conductive structure comprises a connector structure within one of multiple bonded dies or between two bonded dies.

3. The circuit of claim 2, wherein the ADC is configured to output the digital output during an operation of the bonded dies or the two bonded dies.

4. The circuit of claim 1, wherein the plurality of conductive structures comprise at least one of a plurality of through-silicon-vias (TSVs), a plurality of super power rails (SPRs), a uBump, a hybrid bond, or an interconnect structure between dies.

5. The circuit of claim 1, wherein the digital output represents a resistance of the one selected conductive structure.

6. The circuit of claim 1, further comprising a decoder connected to the multiplexer and configured to provide the decoded signal.

7. The circuit of claim 1, further comprising a gain component configured to amplify the test voltage and provide an amplified signal to the ADC.

8. The circuit of claim 1, wherein the ADC is configured to output the digital output based on a clock signal.

9. A circuit, comprising:
a first die;
a second die;
at least one conductive structure between the first die and the second die or within at least one of the first die or the second die;
a signal source within one of the first die or the second die;
at least one switch configured to connect the signal source to the at least one conductive structure through a first wire; and
an analog-to-digital converter (ADC) within one of the first die or the second die, the ADC connected to the at least one conductive structure through a second wire at a first end of the at least one conductive structure and through a third wire at a second end of the at least one conductive structure.

10. The circuit of claim 9, further comprising:
a multiplexer configured to connect the at least one conductive structure and the ADC.

11. The circuit of claim 9, further comprising:
a gain component configured to connect the at least one conductive structure and the ADC.

12. The circuit of claim 9, further comprising:
a resistor configured to connect the ADC to the second end of the at least one conductive structure.

13. The circuit of claim 9, wherein the ADC comprises a sigma delta ADC.

14. The circuit of claim 9, further comprising a first terminal to provide an input signal to the at least one conductive structure, and a second terminal to receive an output of the at least one conductive structure.

15. The circuit of claim 9, further comprising a plurality of conductive structures, including the at least one conductive structure, and a plurality of switches, including the at least one switch,
wherein the ADC is configured to output a sequence of digital outputs corresponding to the plurality of conductive structures.

16. The circuit of claim 15, wherein the first die and the second die are arranged face to face or face to back.

17. A method, comprising:
providing, by a signal source, a test signal to at least one of a plurality of conductive structures based on a decoded signal;
connecting, by a plurality of switches, the signal source to the plurality of conductive structures, respectively, based on the decoded signal;
selecting, by a multiplexer, a test voltage present on the at least one conductive structure, based on the decoded signal; and
providing, by an analog-to-digital converter (ADC), a digital signal based on comparing the test voltage with a reference voltage.

18. The method of claim 17, further comprising amplifying, by a gain component, the test voltage.

19. The method of claim 17, wherein the digital signal represents a resistance of the one selected conductive structure.

20. The method of claim 17, further comprising outputting the signal during an operation of the plurality of conductive structures.
